(19) United States
(12) Patent Application Publication
(10) Pub. No.: US 2022/0013470 A1
(43) Pub. Date: Jan. 13, 2022

(54) SEMICONDUCTOR DEVICE AND TEMPLATE

(71) Applicant: Kioxia Corporation, Tokyo (JP)

(72) Inventor: Kazuhiro TAKAHATA, Yokohama (JP)

(73) Assignee: Kioxia Corporation, Tokyo (JP)

(21) Appl. No.: 17/179,697

(22) Filed: Feb. 19, 2021

(30) Foreign Application Priority Data
Jul. 8, 2020 (JP) 2020-117712

(51) Int. Cl. H01L 23/544; H01L 21/027; G03F 7/20; G03F 9/00

(52) U.S. Cl. CPC H01L 23/544; H01L 21/027; H01L 2223/54426; G03F 9/7042; G03F 7/70633

(57) ABSTRACT

A semiconductor device includes: a semiconductor substrate having a first surface; a device area that is formed on the semiconductor substrate and includes a semiconductor element; and a conductive member that surrounds the device area and extends in a first direction perpendicularly intersecting the first surface. The conductive member is formed on the semiconductor substrate, and includes a first pattern and a second pattern, the second pattern overlapping the first pattern in the first direction. A pitch of the first pattern in a second direction intersecting the first direction is different from a pitch of the second pattern in the second direction.

### CROSS-REFERENCE TO RELATED APPLICATION(S)

This application is based upon and claims the benefit of priority from Japanese Patent Application No. 2020-117712, filed on Jul. 8, 2020, the entire contents of which are incorporated herein by reference.

### FIELD

Embodiments described herein relate generally to a semiconductor device and a template.

### BACKGROUND

In a nanoimprint method, a Moire mark disposed in a scribe line area is known as an alignment mark used for position alignment.

### DESCRIPTION OF THE DRAWINGS

FIG. 1 is a top view illustrating a configuration of a wafer on which semiconductor devices according to at least one embodiment are formed.

FIG. 2 is a top view illustrating a configuration of a shot in the wafer on which the semiconductor devices according to at least one embodiment are formed.

FIG. 3 is a top view illustrating a configuration of the semiconductor device according to at least one embodiment.

FIG. 4 is a bird's eye view illustrating the configuration of the semiconductor device according to at least one embodiment.

FIGS. 5A and 5B are views schematically illustrating a structure of a guard ring in an area R illustrated in FIG. 3.

FIGS. 6A and 6B are views illustrating a modification of line-and-space patterns of the guard ring.

FIGS. 7A and 7B are views illustrating a modification of line-and-space patterns of the guard ring, subsequently to FIGS. 6A and 6B.

FIGS. 8A and 8B are views illustrating a template according to at least one embodiment.

FIG. 9 is a top view illustrating a configuration of a pattern formed on a pattern surface of the template according to at least one embodiment.

FIGS. 10A and 10B are enlarged views of an area S illustrated in FIG. 9.

FIGS. 11A to 11D are views illustrating a process of manufacturing the semiconductor device according to at least one embodiment by using the template according to the embodiment.

FIGS. 12A to 12C are views illustrating the process of manufacturing the semiconductor device according to at least one embodiment, subsequently to FIGS. 11A to 11D.

FIGS. 13A and 13B are views illustrating a modification of the structure of a guard ring forming pattern in the area S illustrated in FIG. 9.

FIGS. 14A to 14D are views illustrating a modification of the process of manufacturing the semiconductor device according to at least one embodiment.

FIGS. 15A to 15E are views illustrating the modification of the process of manufacturing the semiconductor device according to at least one embodiment, subsequently to FIGS. 14A to 14D.

FIGS. 16A to 16D are views illustrating a modification of the process of manufacturing the semiconductor device according to at least one embodiment, subsequently to FIGS. 15A to 15E.

FIGS. 17A to 17C are views illustrating the modification of the process of manufacturing the semiconductor device according to at least one embodiment, subsequently to FIGS. 16A to 16D.

### DETAILED DESCRIPTION

At least one embodiment provides a semiconductor device and a template capable of improving alignment accuracy in a nanoimprint method.

In general, according to at least one embodiment, a semiconductor device includes: a semiconductor substrate having a first surface; a device area formed on the semiconductor substrate and including a semiconductor element; and a conductive member surrounding the device area and extending in a first direction perpendicularly intersecting the first surface. The conductive member includes a first pattern, and a second pattern, the second pattern overlapping the first pattern in the first direction, and pitches of the first pattern and the second pattern are different in a second direction intersecting the first direction.

Hereinafter, the at least one embodiment will be described with reference to drawings. In the description of drawings to be described below, the same or similar portions are denoted by the same or similar reference numerals. Meanwhile, the drawings are schematic, and the relationship between the thickness and the planar dimension, and the like are different from actual ones.

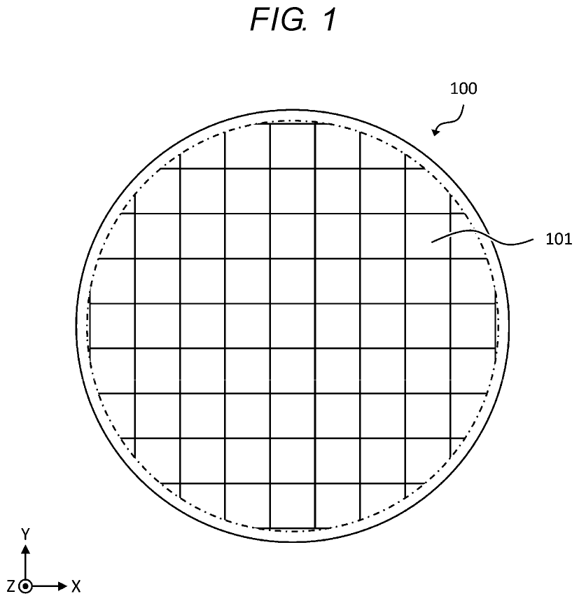

First, a semiconductor device according to at least one embodiment will be described with reference to FIG. 1 to FIGS. 7A and 7B. Hereinafter, a NAND-type flash memory will be described as an example of the semiconductor device.

FIG. 1 is a top view illustrating a wafer 100 on which the semiconductor devices according to at least one embodiment are formed. FIG. 1 illustrates the wafer 100 on which the semiconductor devices are formed, and the layout of shots set on the wafer 100. An area represented by a square on the wafer 100 corresponds to a shot 101. The shot 101 is an exposure unit of photolithography or a pressing unit of imprint lithography. In other words, the shot 101 is an area that can be exposed by one exposure or an area that is imprintable by one pressing.

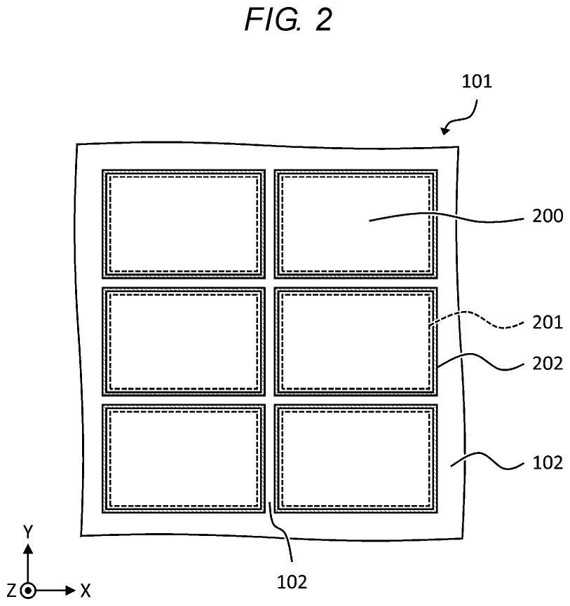

FIG. 2 is a top view illustrating the layout of the shot 101. As illustrated in FIG. 2, the shot 101 includes a plurality of chip areas 200. Here, a case where the shot 101 includes six chip areas 200 is illustrated. The chip area 200 includes a device area 201 and a peripheral area 202. In the device area 201, a multilayer structure circuit including various semiconductor elements, wirings or the like constituting a NAND-type flash memory is formed. Ascribe line 102 is provided between the six chip areas and on the outer peripheries thereof.

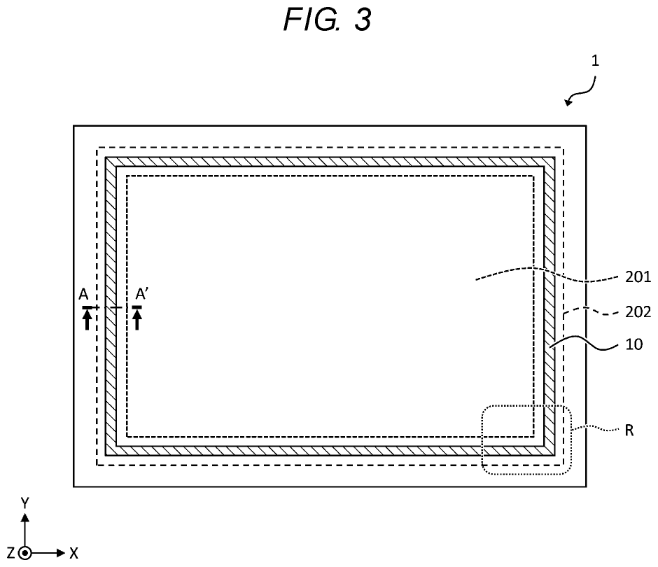

FIG. 3 is a top view illustrating the configuration of the semiconductor device according to at least one embodiment. A semiconductor device 1 illustrated in FIG. 3 is obtained by cutting the plurality of chip areas 200 formed on the wafer 100 as illustrated in FIG. 2 by dicing. The wafer 100 is cut along the scribe line 102 by a dicer blade. Similar to the chip area 200 in FIG. 2, the semiconductor device 1 includes the device area 201 and the peripheral area 202. A guard ring 10 is provided in the peripheral area 202 of the semiconductor device 1.

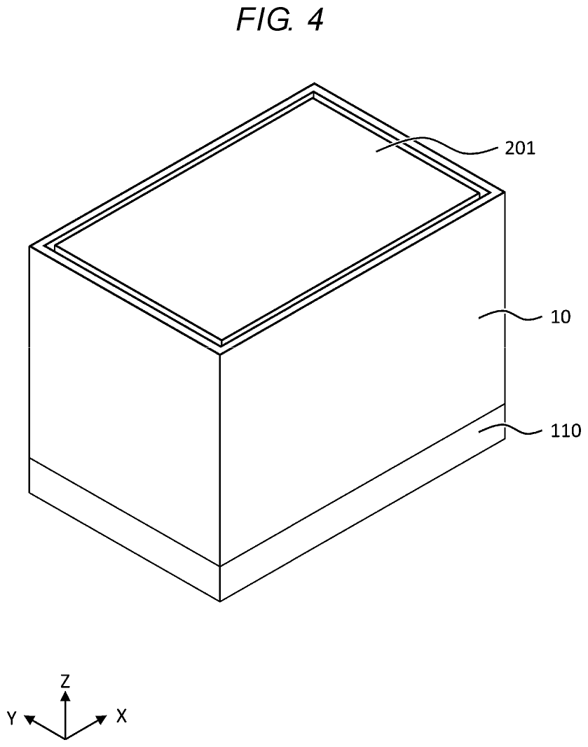

FIG. 4 is a bird's eye view illustrating the configuration of the semiconductor device according to at least one embodiment. As illustrated in FIG. 4, in the semiconductor device 1, the guard ring 10 and the device area 201 are formed on a semiconductor substrate 110. An insulating film is present between the scribe line 102 and the peripheral area 202 other than the guard ring 10 in FIG. 2, and between the device area 201 and the guard ring 10 in FIG. 3, but illustration of the insulating film is omitted in FIG. 4. As illustrated in FIG. 4, the guard ring 10 surrounds the periphery of the device area 201. The guard ring 10 may have a rectangular annular structure that has sides extending in the X direction and the Y direction, and has a height in the Z direction. The layer structure of the guard ring 10 is the same as the layer structure of the multilayer structure circuit in the device area 201. Specifically, in the guard ring 10, conductive members having an annular structure provided on the outer periphery of the device area 201 are stacked in the Z direction.

In order to stabilize potentials of a power supply line, a well, etc., the potential of the guard ring 10 can be set to the same potential (ground potential VSS) over the entire outer periphery of the semiconductor device 1. The guard ring 10 prevents, for example, intrusion of charged impurities, etc. from silicon exposed on the end portion of the semiconductor device 1. For example, during a dicing process, when a crack or peeling of an interlayer insulating film or the like occurs on the end portion of the semiconductor device 1, the guard ring 10 prevents the crack or the peeling from reaching the inside of the semiconductor device 1, that is, the device area 201. The guard ring 10 prevents water or the like from penetrating into the device area 201 from the end portion of the semiconductor device 1. Further, the guard ring 10 prevents intrusion of surge from the outside during a dicing process, or a packaging process, thereby preventing the occurrence of overcurrent in the above described device area 201.

FIG. 4 schematically illustrates an example where one guard ring 10 surrounding the device area 201 is provided, but a plurality of guard rings 10 surrounding the device area 201 may be provided.

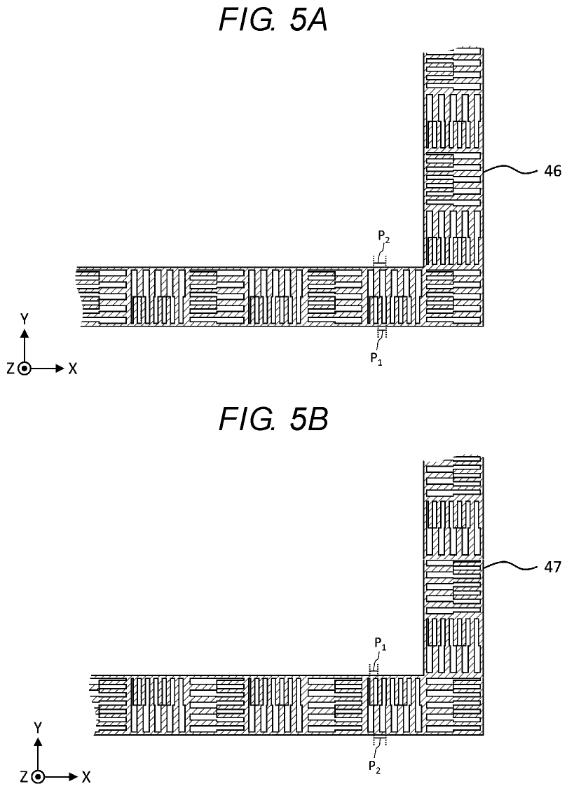

FIGS. 5A and 5B are views schematically illustrating the structure of the guard ring 10 in an area R illustrated in FIG. 3. Here, for convenience, in the guard ring 10, layers corresponding to the respective layers in the multilayer structure circuit formed in the above described device area 201 are formed in the Z direction. When the guard ring 10 is formed, wiring or the like in the device area 201 in the same layer is also formed at the same time. However, the respective layers in the guard ring 10 do not necessarily have boundaries. FIG. 5A illustrates the structure of the guard ring 10 in the area R in the n^{th} layer (n is an integer of 2 or more) from the semiconductor substrate side. FIG. 5B illustrates the structure of the guard ring 10 in the area R in the n−1^{th} layer from the semiconductor substrate side. The device area 201 and the above described insulating film are omitted.

As illustrated in FIGS. 5A and 5B, line-and-space patterns with a pitch P1 and a pitch P2 are formed in the n^{th} layer and the n−1^{th} layer. Hereinafter, a line-and-space pattern having the pitch P1 may be referred to as a P1 pattern, and a line-and-space pattern having the pitch P2 may be referred to as a P2 pattern. The line-and-space patterns in the n^{th} layer and the n−1^{th} layer are formed by using conductive members like those in other layers of the guard ring 10. Hereinafter, the conductive member formed in the n^{th} layer of an area where the guard ring 10 is formed when viewed from the Z direction will be referred to as a pattern 46. Likewise, the conductive member formed in the n−1^{th} layer of the area where the guard ring 10 is formed when viewed from the Z direction will be referred to as a pattern 47. The pitch P1 and the pitch P2 are slightly different from each other. FIGS. 5A and 5B illustrate a case where the pitch P2 is larger than the pitch P1. As illustrated in FIGS. 5A and 5B, in the pattern 46 and the pattern 47, positions of the P1 pattern and the P2 pattern are replaced with each other. The pattern 47 illustrated in FIG. 5B functions as an alignment mark used for position alignment between a template for nanoimprint and the semiconductor device when the pattern 46, wiring or the like is formed by using a nanoimprint method. Further, the pattern 46 and the pattern 47 are provided while overlapping in the up-down direction when viewed from the Z direction such that at least one ring-shaped pattern is formed. The ring-shaped pattern becomes the guard ring 10.

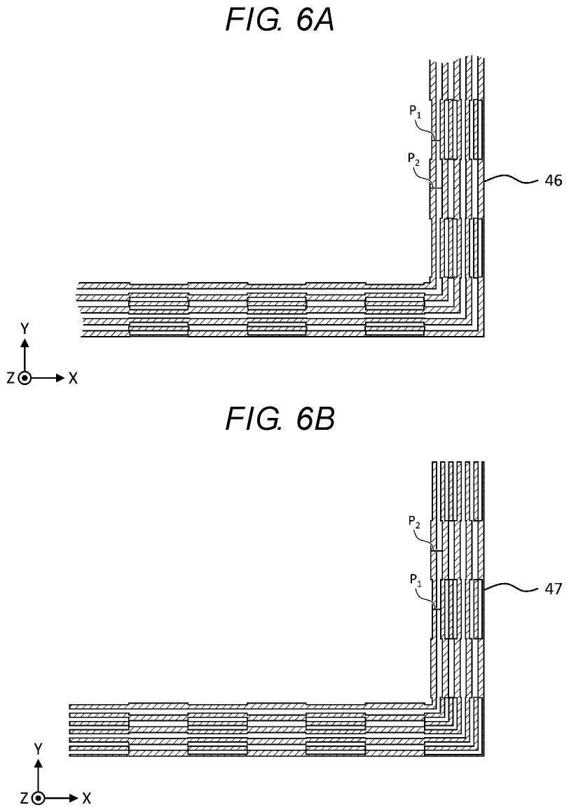

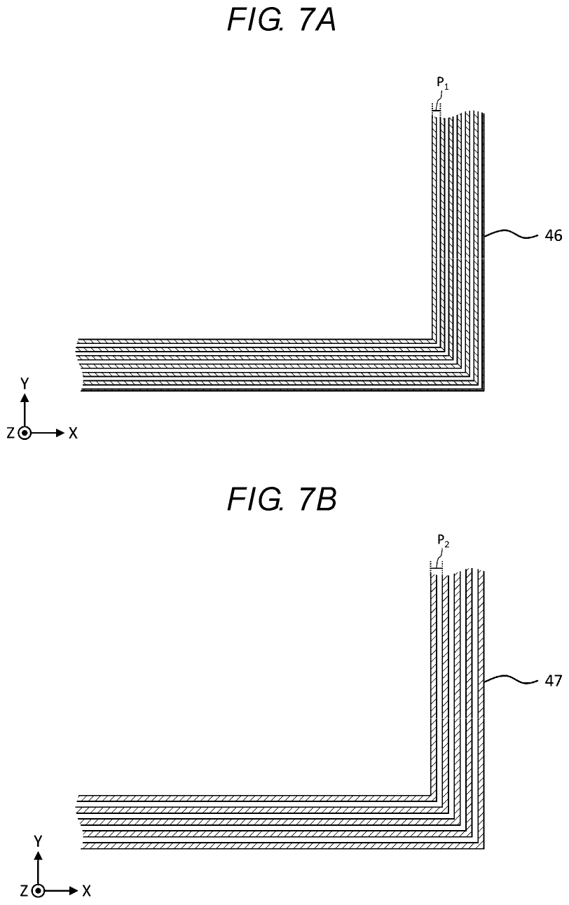

FIGS. 6A and 6B and FIGS. 7A and 7B are views illustrating modifications of the pattern 46 and the pattern 47. As illustrated in FIGS. 6A and 6B, in the pattern 46 and the pattern 47, the P1 pattern and the P2 pattern may be alternately formed along the directions in which the guard ring extends in the X direction and the Y direction. Further, as illustrated in FIGS. 7A and 7B, only the P1 pattern may be formed in the pattern 46, and only the P2 pattern may be formed in the pattern 47. However, in each of the modifications, in the pattern 46 and the pattern 47, positions of the P1 pattern and the P2 pattern are replaced with each other. Further, as in at least one embodiment in FIGS. 5A and 5B, the pattern 46 and the pattern 47 are provided while overlapping in the up-down direction when viewed from the Z direction such that at least one ring-shaped pattern is formed. The ring-shaped pattern becomes the guard ring 10.

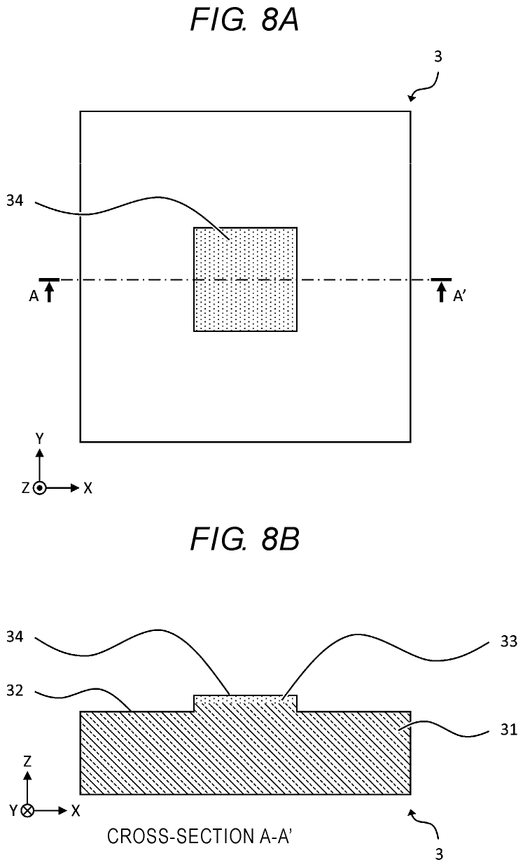

Next, descriptions will be made on a method of manufacturing the semiconductor device according to at least one embodiment with reference to FIGS. 8A and 8B to FIGS. 17A to 17C. Here, descriptions will be made on a process of forming the pattern 46, wiring, and the like in the n^{th} layer, on an upper surface of the pattern 47 by using a nanoimprint method, after the pattern 47 illustrated in FIG. 5B, wiring, and the like are formed in the n−1^{th} layer.

FIGS. 8A and 8B are views illustrating a template used for the method of manufacturing the semiconductor device according to at least one embodiment. FIG. 8A is a plan view of a template 3 when viewed from the Z direction. FIG. 8B is a sectional view of the template 3 taken along AA′ when viewed from the Y direction. The template 3 is obtained by processing a substrate 31 that is quadrilateral when viewed in the Z direction. In the case of nanoimprint lithography using photocuring, the template 3 contains, for example, quartz (a transparent material).

At the center of a main surface 32 of the substrate 31, a structure 33 protruding in a convex shape from the main surface 32 is provided. The structure 33 has a pattern surface 34. On the pattern surface 34, an uneven structure (uneven pattern) including a transfer pattern or an alignment mark is formed.

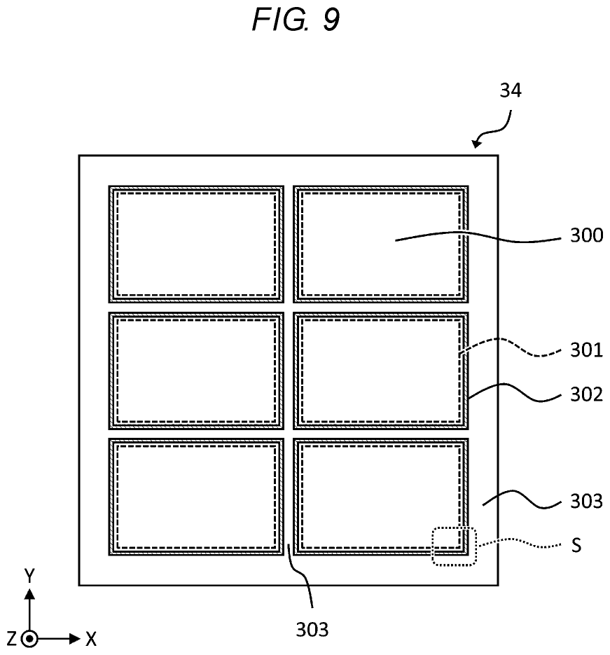

FIG. 9 is a top view illustrating the pattern formed on the pattern surface 34. As illustrated in FIG. 9, a plurality of chip forming patterns 300 is formed on the pattern surface 34. Here, a case where the pattern surface 34 includes six chip forming patterns 300 is illustrated. The chip forming pattern 300 includes a device area forming pattern 301 and a guard ring forming pattern 302. A scribe line pattern 303 is provided between the six chip forming patterns 300 and on the outer peripheries thereof.

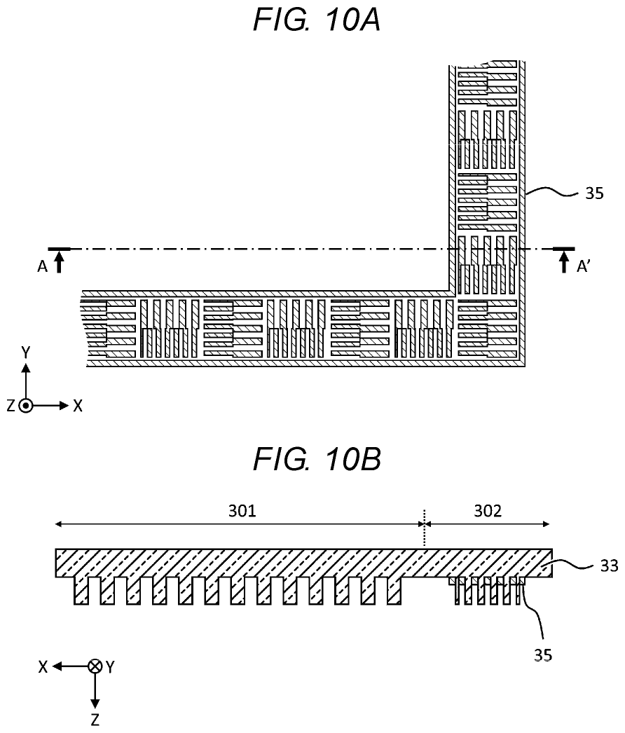

FIG. 10A is an enlarged view of an area S illustrated in FIG. 9. FIG. 10B is a cross-sectional view of the structure 33 of the template 3 taken along AA′ when viewed from the Y direction. In FIG. 10A, illustration of the device area forming pattern 301 is omitted. As illustrated in FIGS. 10A and 10B, convex portions having the same shape as the pattern 46 formed in the n^{th} layer of the semiconductor device 1 are formed in the structure 33, and a metal film 35 is provided in the periphery of the convex portions in the guard ring forming pattern 302 and in concave portions between the convex portions. Thus, as illustrated in FIG. 10A, the metal film 35 has an inverted pattern of the pattern 46. The metal film 35 contains at least one material having a refractive index significantly different from the template 3, such as chromium, molybdenum, tantalum, tungsten, zirconium and titanium. The metal film 35 in FIGS. 10A and 10B has a ring-shaped pattern surrounding the device area forming pattern 301, but the ring-shaped pattern may or may not be present.

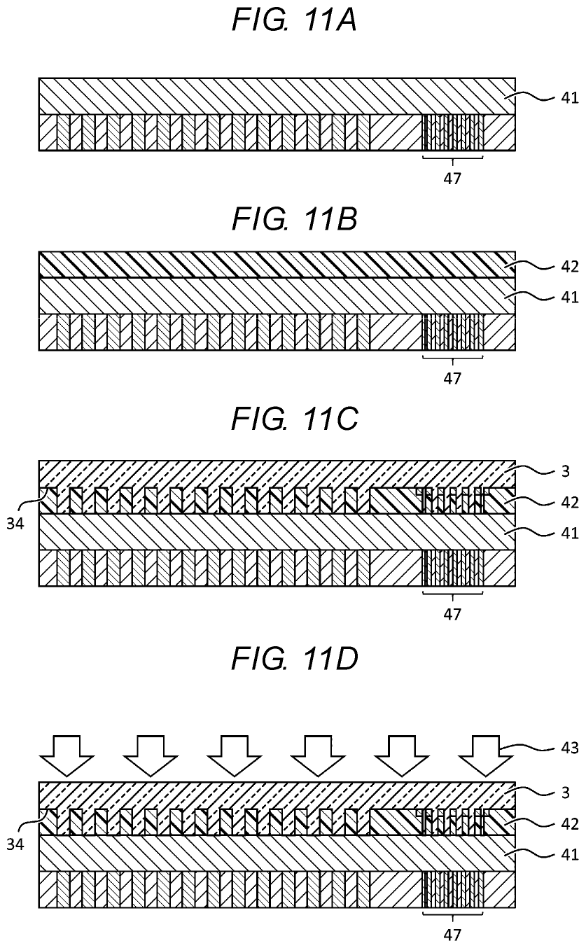

Next, descriptions will be made on a process of forming a conductive member 44 in the n^{th} layer of the semiconductor device 1 by using the template 3. The pattern 46, wiring, or the like is formed by the conductive member 44. In FIGS. 11A to 11D and subsequent drawings, illustration of layers below the n−1^{th} layer is omitted. First, as illustrated in FIG. 11A, an insulating film 41 is formed on the n−1^{th} layer of the semiconductor device 1.

Next, as illustrated in FIG. 11B, a photocurable resist 42 is applied to the insulating film 41.

Next, as illustrated in FIG. 11C, the pattern surface of the template 3 is brought into contact with the photocurable resist 42. At this time, the inside of a concave structure of the pattern surface 34 is filled with the photocurable resist 42. At this time, as illustrated in FIGS. 5A and 5B, in the pattern 46 and the pattern 47, positions of the P1 pattern and the P2 pattern are reversed. Thus, when the pattern surface 34 of the template 3 is brought into contact with the photocurable resist 42 and alignment light is radiated from the template side, a Moire fringe is generated by the pattern 47 and the metal film 35. Misalignment may be detected based on a peak position of the Moire fringe, and then the position of the template 3 may be adjusted in the X direction and the Y direction so as to correct the misalignment. For the alignment light, intensity and wavelength of such a degree that the photocurable resist 42 is not cured are selected.

Next, as illustrated in FIG. 11D, the photocurable resist 42 is irradiated with light 43 in a state where the uneven pattern of the pattern surface 34 is in contact with the photocurable resist 42. Accordingly, the photocurable resist 42 is cured.

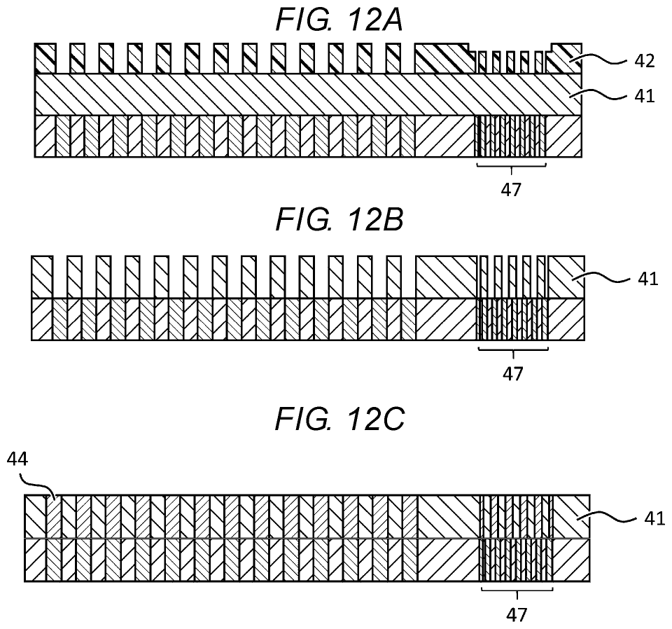

Next, as illustrated in FIG. 12A, the uneven pattern of the pattern surface 34 is peeled from the cured photocurable resist 42. Then, as illustrated in FIG. 12B, the photocurable resist 42 separated from the uneven pattern of the pattern surface 34 is used as a mask to etch the insulating film 41.

Next, as illustrated in FIG. 12C, the conductive member 44 is embedded in the groove formed by etching the insulating film 41. Accordingly, wiring or the like or the pattern 46 illustrated in FIG. 5A is formed.

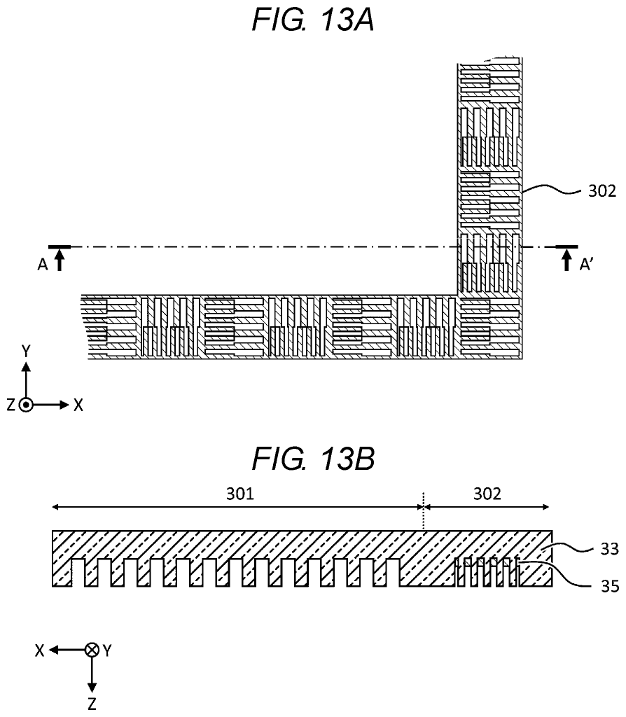

FIGS. 13A and 13B to FIGS. 17A to 17C are views illustrating a modification of the method of manufacturing the semiconductor device according to at least one embodiment. FIGS. 13A and 13B are views illustrating a template used for the method of manufacturing the semiconductor device of the modification. FIG. 13B is a cross-sectional view of the structure 33 of the template 3 taken along AA′ when viewed from the Y direction. As illustrated in FIGS. 13A and 13B, in the template 3 of the modification, the unevenness is inverted from that of the template 3 illustrated in FIGS. 10A and 10B. Thus, the metal film 35 provided in the guard ring forming pattern 302 has the same pattern as the pattern 46.

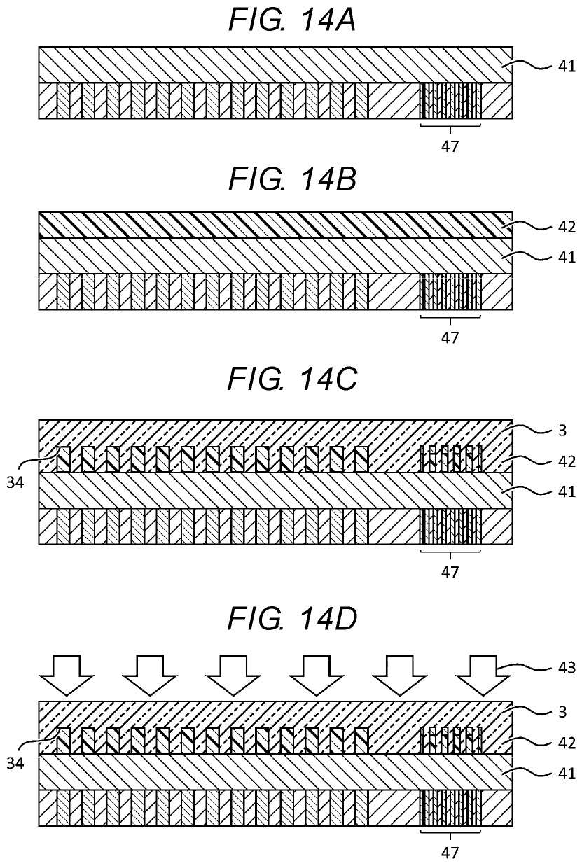

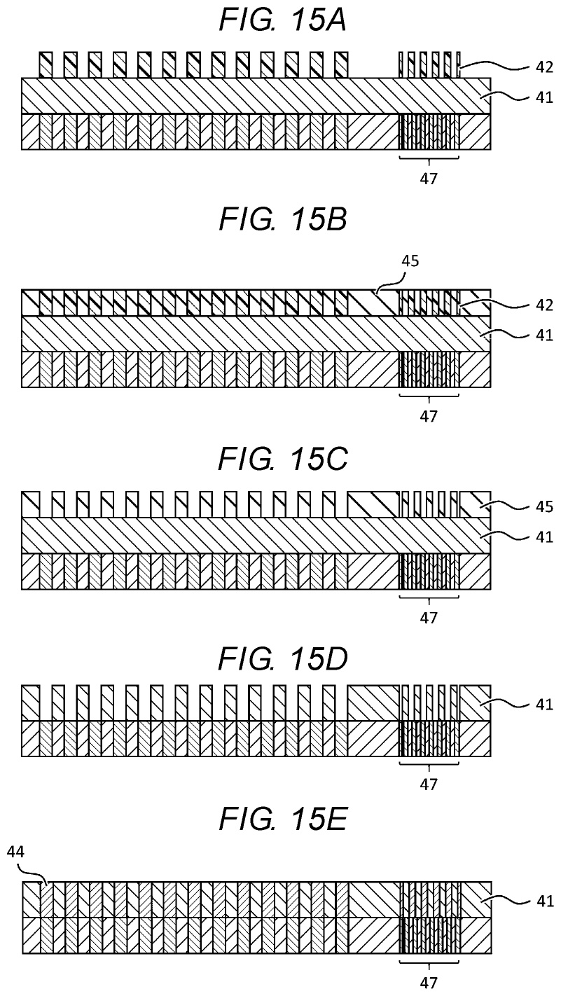

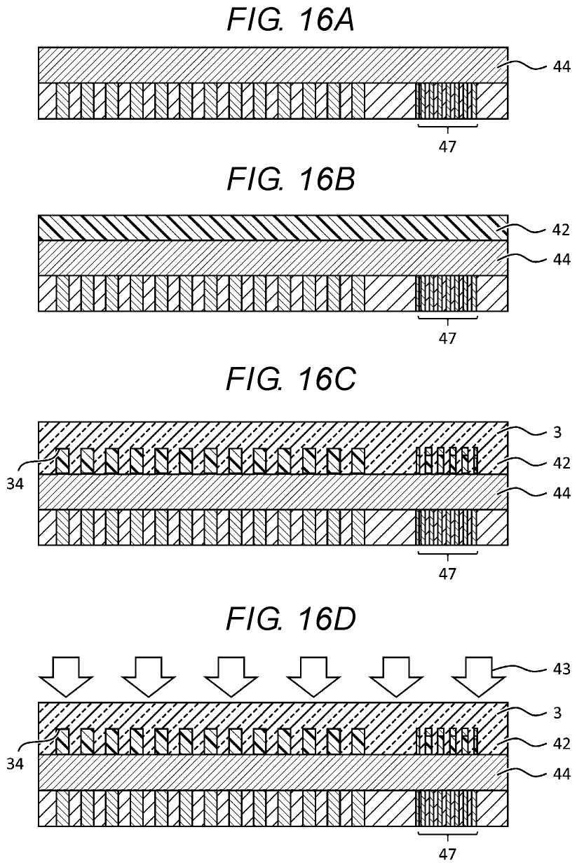

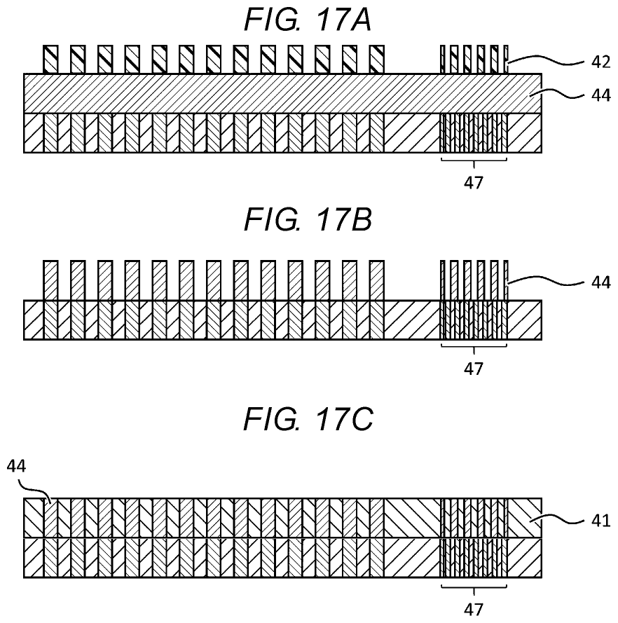

Next, descriptions will be made on a process of forming the conductive member 44 in the n^{th} layer by using the template 3 of the modification. The process of forming the conductive member 44 by using the template 3 of the modification may include two methods, that is, a process illustrated in FIGS. 14A to 14D to FIGS. 15A to 15E and a process illustrated in FIGS. 16A to 16D and FIGS. 17A to 17C. First, the process illustrated in FIGS. 14A to 14D and FIGS. 15A to 15E will be described.

First, as illustrated in FIG. 14A, the insulating film 41 is formed on the n−1^{th} layer of the semiconductor device 1. As described above, the n−1^{th} layer includes the pattern 47, wiring, and the like.

Next, as illustrated in FIG. 14B, the photocurable resist 42 is applied to the insulating film 41.

Next, as illustrated in FIG. 14C, the pattern surface of the template 3 is brought into contact with the photocurable resist 42. At this time, the inside of the concave structure of the pattern surface 34 is filled with the photocurable resist 42. As in the above described at least one embodiment, misalignment may be corrected by using a Moire fringe.

Next, as illustrated in FIG. 14D, the photocurable resist 42 is irradiated with the light 43 in a state where the uneven pattern of the pattern surface 34 is in contact with the photocurable resist 42. Accordingly, the photocurable resist 42 is cured.

Next, as illustrated in FIG. 15A, the uneven pattern of the pattern surface 34 is peeled from the cured photocurable resist 42.

Next, as illustrated in FIG. 15B, a coating film 45 is formed by using a material having an etching rate different from the photocurable resist 42. Accordingly, the cured photocurable resist 42 is embedded in the coating film 45.

Next, as illustrated in FIG. 15C, the photocurable resist 42 is etched. Then, as illustrated in FIG. 15D, the coating film 45 is used as a mask to etch the insulating film 41.

Next, as illustrated in FIG. 15E, the conductive member 44 is embedded in the groove formed by etching the insulating film 41. Accordingly, wiring or the like or the pattern 46 illustrated in FIG. 5A is formed.

Subsequently, the process illustrated in FIGS. 16A to 16D and FIGS. 17A to 17C will be described. First, as illustrated in FIG. 16A, the conductive member 44 is formed on the n−1^{th} layer of the semiconductor device 1.

Next, as illustrated in FIG. 16B, the photocurable resist 42 is applied to the conductive member 44.

Next, as illustrated in FIG. 16C, the pattern surface of the template 3 is brought into contact with the photocurable resist 42. At this time, the inside of the concave structure of the pattern surface 34 is filled with the photocurable resist 42. At this time, as in the above described embodiment, misalignment may be corrected by using a Moire fringe.

Next, as illustrated in FIG. 16D, the photocurable resist 42 is irradiated with the light 43 in a state where the uneven pattern of the pattern surface 34 is in contact with the photocurable resist 42. Accordingly, the photocurable resist 42 is cured.

Next, as illustrated in FIG. 17A, the uneven pattern of the pattern surface 34 is peeled from the cured photocurable resist 42.

Next, as illustrated in FIG. 17B, the photocurable resist 42 separated from the uneven pattern of the pattern surface 34 is used as a mask to etch the conductive member 44. Then, as illustrated in FIG. 17C, the insulating film 41 is embedded in the groove formed by etching the conductive member 44. Accordingly, wiring or the like or the pattern 46 illustrated in FIG. 5A is formed.

Until now, descriptions have been made on a method of manufacturing the semiconductor device and the modifications thereof when the pattern 47 illustrated in FIG. 5B, wiring or the like is formed in the n−1^{th} layer and, on the upper surface thereof, and the pattern 46, wiring or the like is formed in the n^{th} layer by using a nanoimprint method. However, at least one embodiment and the modifications thereof are similarly applicable regardless of which of patterns illustrated in FIGS. 5A and 5B to FIGS. 7A and 7B is the pattern of the guard ring 10 formed in the n−1^{th} layer.

In the semiconductor device and the template according to at least one embodiment, line-and-space patterns for alignment, which are disposed at four corners of the scribe line 102 in each shot, are generally formed in the area where the guard ring 10 is formed when viewed from the Z direction. Thus, it is possible to detect deviation in the entire shot, thereby improving the accuracy of alignment.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor device comprising:
a semiconductor substrate having a first surface;
a device area formed on the semiconductor substrate and including a semiconductor element; and
a conductive member surrounding the device area and extending in a first direction perpendicularly intersecting the first surface,
wherein the conductive member is formed on the semiconductor substrate, and includes a first pattern and a second pattern, the second pattern overlapping the first pattern in the first direction, and
a pitch of the first pattern in a second direction intersecting the first direction is different from a pitch of the second pattern in the second direction.

2. The semiconductor device according to claim 1, wherein the first pattern and the second pattern at least partially overlap vertically when viewed from the first direction, and
the conductive member includes at least one ring-shaped pattern.

3. The semiconductor device according to claim 1, wherein the first pattern and the second pattern have at least two or more types of patterns having pitches different from each other.

4. The semiconductor device according to claim 1, wherein the first pattern and the second pattern have a plurality of line-and-space patterns extending in the second direction, and the first pattern and the second pattern have a plurality of line-and-space patterns extending in a third direction intersecting the first direction and the second direction.

5. The semiconductor device according to claim 1, wherein the conductive member includes a guard ring.

6. The semiconductor device according to claim 1, wherein at least one of the first pattern or the second pattern is an alignment mark.

7. The semiconductor device according to claim 1, wherein the alignment mark includes a Moire alignment mark.

8. The semiconductor device according to claim 1, wherein the semiconductor device includes a NAND memory.

9. The semiconductor device according to claim 1, wherein the conductive member has a quadrilateral shape.

10. The semiconductor device according to claim 1, wherein the first pattern contacts the second pattern.

11. The semiconductor device according to claim 1, wherein the first and second patterns are arranged as consecutive patterns in the first direction.

12. The semiconductor device according to claim 1, wherein a layer structure of the conductive member includes a same metal layer as a layer structure of the semiconductor element.

13. A template comprising:
a substrate;
a first pattern disposed in a first area of the substrate; and
a second pattern disposed at an outer periphery of the first area, and the second pattern includes a metal film formed on the substrate,
wherein the second pattern includes a pattern surrounding the first area.

14. The template according to claim 13, wherein the second pattern includes at least one ring-shaped pattern.

15. The template according to claim 13, wherein the second pattern has at least two or more types of patterns having pitches different from each other.

16. The template according to claim 13, wherein the second pattern has a plurality of line-and-space patterns extending in a first direction, and the second pattern has a plurality of line-and-space patterns extending in a second direction intersecting the first direction.

17. The template according to claim 13, wherein the metal film includes a metal having a different refractive index from the substrate.

18. The template according to claim 13, wherein the metal film contains at least one of chromium, molybdenum, tantalum, tungsten, zirconium or titanium.

19. A semiconductor device comprising:
a semiconductor substrate having a first surface;
a device area formed on the semiconductor substrate and including a semiconductor element; and
a conductive member surrounding the device area and extending in a first direction perpendicularly intersecting the first surface,
wherein the conductive member is formed on the semiconductor substrate, and includes a first pattern and a second pattern, the second pattern overlapping the first pattern in the first direction, and
wherein at least one of the first pattern or the second pattern is a Moire alignment mark.

20. The semiconductor device according to claim 19, wherein the conductive member includes a guard ring.
